(19) United States
(12) Patent Application Publication
(10) Pub. No.: US 2026/0255646 A1
(43) Pub. Date: Aug. 27, 2026

(54) SEMICONDUCTOR DEVICE

(71) Applicant: Kioxia Corporation, Tokyo (JP)

(72) Inventors: Tadayoshi UECHI, Kawasaki Kanagawa (JP); Takahisa KANEMURA, Yokohama Kanagawa (JP); Takashi IZUMIDA, Kamakura Kanagawa (JP); Takeshi SHIMANE, Matsudo Chiba (JP)

(21) Appl. No.: 19/327,762

(22) Filed: Sep. 12, 2025

(30) Foreign Application Priority Data
Feb. 27, 2025 (JP) 2025-030026

(51) Int. Cl. H10D 64/00

(52) U.S. Cl. CPC H10D 64/112

(57) ABSTRACT

A semiconductor device includes a semiconductor region including drain and source regions, a channel region between the drain and source regions, an insulating layer on the semiconductor region, a gate electrode on the insulating layer above the channel region, a drain contact connected to the drain region, and a ring-shaped electrode on the insulating layer, spaced from the gate electrode, and surrounding the drain contact. The gate electrode includes a first electrode portion and a second electrode portion that faces the ring-shaped electrode. The ring-shaped electrode includes a third electrode portion and a fourth electrode portion that faces the gate electrode. A work function of the second electrode portion or the fourth electrode portion is different from a work function of the first electrode portion.

### CROSS-REFERENCE TO RELATED APPLICATIONS

This application is based upon and claims the benefit of priority from Japanese Patent Application No. 2025-030026, filed February 27, 2025, the entire contents of which are incorporated herein by reference.

### FIELD

Embodiments described herein relate generally to a semiconductor device.

### BACKGROUND

For MOS transistors, it is desirable to minimize characteristic variations and suppress degradation in breakdown voltage.

### BRIEF DESCRIPTION OF THE DRAWINGS

FIG. 1 is a sectional view schematically showing a basic configuration of a semiconductor device according to an embodiment.

FIG. 2 is a planar pattern diagram schematically showing the basic configuration of the semiconductor device according to the embodiment.

FIGS. 3A, 3B, and 3C are diagrams showing changes in voltage-current characteristics when a work function of an electrode is changed according to embodiments.

FIG. 4 is a diagram showing an electric field distribution in a region between a gate electrode and a ring-shaped electrode in the semiconductor device according to the embodiment.

FIG. 5 is a sectional view schematically showing a configuration of a first specific example of the semiconductor device according to the embodiment.

FIG. 6 is a sectional view schematically showing a configuration of a second specific example of the semiconductor device according to the embodiment.

FIG. 7 is a sectional view schematically showing a configuration of a third specific example of the semiconductor device according to the embodiment.

FIG. 8 is a sectional view schematically showing a configuration of a fourth specific example of the semiconductor device according to the embodiment.

FIG. 9 is a sectional view schematically showing a configuration of a fifth specific example of the semiconductor device according to the embodiment.

### DETAILED DESCRIPTION

Embodiments provide a semiconductor device capable of restraining variation in characteristics and degradation of the breakdown voltage of a MOS transistor.

In general, according to one embodiment, a semiconductor device includes: a semiconductor region including a drain region, a source region, and a channel region between the drain region and the source region; an insulating layer provided on the semiconductor region; a gate electrode provided on the insulating layer above the channel region; a drain contact connected to the drain region; and a first ring-shaped electrode that is provided on the insulating layer to be spaced from the gate electrode and is provided so as to surround the drain contact, wherein the gate electrode includes a first electrode portion that is in contact with the insulating layer, and a second electrode portion that is adjacent to the first electrode portion, the second electrode portion including a portion that is in contact with the insulating layer and faces the ring-shaped electrode, the first ring-shaped electrode includes a third electrode portion that is in contact with the insulating layer, and a fourth electrode portion that is adjacent to the third electrode portion, the fourth electrode portion including a portion that is in contact with the insulating layer and faces the gate electrode, and a work function of the second electrode portion or the fourth electrode portion is different from a work function of the first electrode portion.

Hereafter, embodiments will be described with reference to the drawings.

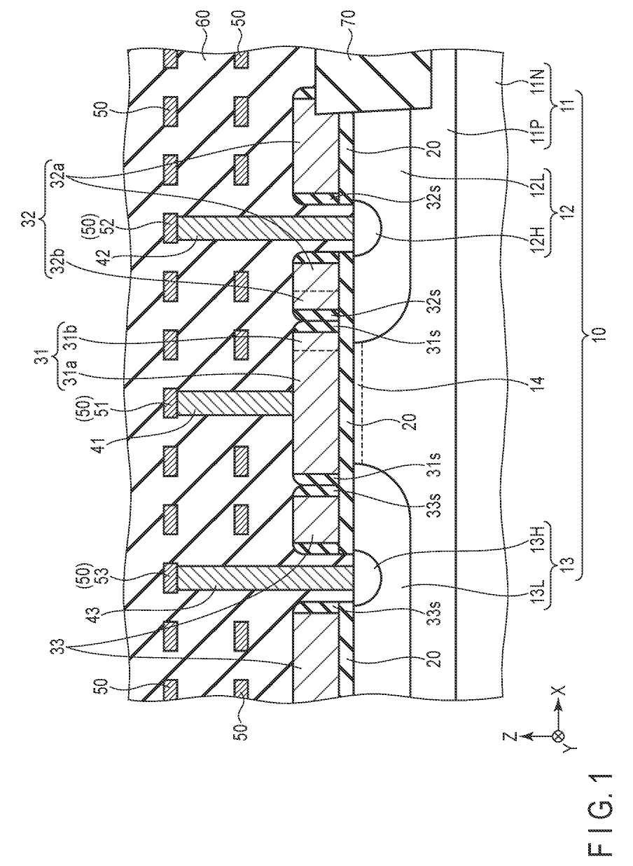

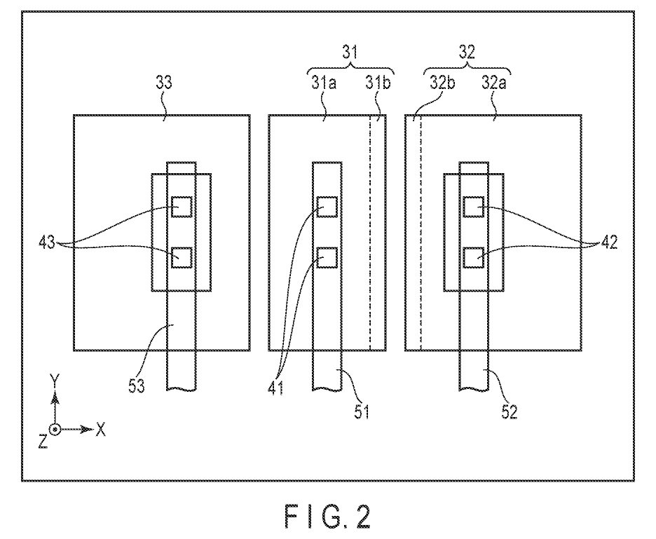

FIG. 1 is a sectional view schematically showing a basic configuration of a semiconductor device according to the present embodiment. FIG. 2 is a planar pattern diagram schematically showing a basic configuration of the semiconductor device according to the present embodiment. The semiconductor device according to the present embodiment is mainly employed as a MOS transistor in high voltage applications.

The semiconductor device according to the present embodiment includes a semiconductor region 10, an insulating layer 20, a gate electrode 31, a ring-shaped electrode 32, a ring-shaped electrode 33, contacts (e.g., a gate contact 41, a drain contact 42, and a source contact 43), lines 50, an insulating region 60, and an element isolation insulating layer 70.

The semiconductor region 10 is a region containing silicon as a main component, and is provided in a semiconductor substrate such as a silicon substrate. The semiconductor region 10 includes a well region 11, a drain region 12, a source region 13, and a channel region 14.

The well region 11 includes an N-type well region 11N containing an N-type impurity and a P-type well region 11P containing a P-type impurity.

The drain region 12 includes a low concentration region 12L containing the N-type impurity having a relatively low concentration and a high concentration region 12H containing the N-type impurity having a relatively high concentration. Likewise, the source region 13 includes a low concentration region 13L containing the N-type impurity having a relatively low concentration and a high concentration region 13H containing the N-type impurity having a relatively high concentration.

The channel region 14 is a region between the drain region 12 and the source region 13, and is a region in which a channel of an N-type MOS transistor is formed.

The insulating layer 20 is provided on the semiconductor region 10, is formed of silicon oxide or the like, and includes a portion that functions as a gate insulating layer of the MOS transistor.

The gate electrode 31 is provided on the insulating layer 20 above the channel region 14, and functions as a gate electrode of the MOS transistor. On a sidewall of the gate electrode 31, a sidewall insulating layer 31s is provided.

The ring-shaped electrode 32 is provided on the insulating layer 20 to be spaced from the gate electrode 31 and is provided so as to surround the drain contact 42. Namely, as viewed along the Z-direction, a pattern of the ring-shaped electrode 32 is provided so as to surround a pattern of the drain contact 42. Likewise, the ring-shaped electrode 33 is provided on the insulating layer 20 to be spaced from the gate electrode 31 and is provided so as to surround the source contact 43. Namely, as viewed along the Z-direction, a pattern of the ring-shaped electrode 33 is provided so as to surround a pattern of the source contact 43. Moreover, on a sidewall of the ring-shaped electrode 32, a sidewall insulating layer 32s is provided, and on a sidewall of the ring-shaped electrode 33, a sidewall insulating layer 33s is provided.

The gate contact 41 is connected to the gate electrode 31, the drain contact 42 is connected to the high concentration region 12H of the drain region 12, and the source contact 43 is connected to the high concentration region 13H of the source region 13. Notably, the drain contact 42 and the ring-shaped electrode 32 are preferably commonly connected, and the source contact 43 and the ring-shaped electrode 33 are preferably commonly connected.

The plurality of lines 50 are provided in the insulating region 60, and include a line 51 connected to the gate contact 41, a line 52 connected to the drain contact 42, and a line 53 connected to the source contact 43.

The aforementioned gate electrode 31 includes an electrode portion 31a and an electrode portion 31b. Both the electrode portion 31a and the electrode portion 31b are in contact with the insulating layer 20. The electrode portion 31a functions as a main portion of the gate electrode 31. The electrode portion 31b is adjacent to the electrode portion 31a, and includes a portion facing the ring-shaped electrode 32.

The aforementioned ring-shaped electrode 32 includes an electrode portion 32a and an electrode portion 32b. Both the electrode portion 32a and the electrode portion 32b are in contact with the insulating layer 20. The electrode portion 32b is adjacent to the electrode portion 32a, and includes a portion facing the gate electrode 31.

At least one of a work function of the electrode portion 31b and a work function of the electrode portion 32b is different from a work function of the electrode portion 31a. First, second, and third examples of the work functions are given below.

The first example is a case where the work function of the electrode portion 31b is different from the work function of the electrode portion 31a and the work function of the electrode portion 32b is equal to the work function of the electrode portion 31a. In this case, the work function of the electrode portion 31b is preferably lower than the work function of the electrode portion 31a.

The second example is a case where the work function of the electrode portion 32b is different from the work function of the electrode portion 31a and the work function of the electrode portion 31b is equal to the work function of the electrode portion 31a. In this case, the work function of the electrode portion 32b is preferably higher than the work function of the electrode portion 31a.

The third example is a case where the work function of the electrode portion 31b is different from the work function of the electrode portion 31a and the work function of the electrode portion 32b is also different from the work function of the electrode portion 31a. In this case, the work function of the electrode portion 31b is preferably lower than the work function of the electrode portion 31a, and the work function of the electrode portion 32b is preferably higher than the work function of the electrode portion 31a.

In each case of the first example, the second example, and the third example, the work function of the electrode portion 32a is not limited to a particular work function. Namely, the work function of the electrode portion 32a may be equal to or different from the work function of the electrode portion 31a. Moreover, the work function of the electrode portion 32a may be equal to or different from the work function of the electrode portion 31b. Moreover, the work function of the electrode portion 32a may be equal to or different from the work function of the electrode portion 32b. Note that the work function of the electrode portion 32a is normally equal to at least one of the work function of the electrode portion 31a and the work function of the electrode portion 32b.

Moreover, among the electrode portions 31a, 31b, 32a, and 32b, those having the same work function are formed using a common process and are therefore formed of the same material.

A work function of the ring-shaped electrode 33 is also not specifically limited to a particular work function. For example, the work function of the ring-shaped electrode 33 may be equal to the work function of the electrode portion 31a of the gate electrode 31.

With the configuration as described above, the present embodiment can provide a semiconductor device capable of minimizing characteristic variations and degradation of the breakdown voltage of the MOS transistor as described below.

In the present embodiment, the ring-shaped electrode 32 is provided on the drain region 12 side, and the ring-shaped electrode 33 is provided on the source region 13 side. Providing the ring-shaped electrodes 32 and 33 in such a manner can suppress influence from the lines 50. If such ring-shaped electrodes are not provided, there is concern that the influence of an electric field from the lines 50 causes potentials of the drain region 12 and the source region 13 to vary, which results in variation in characteristics of the MOS transistor.

In the present embodiment, the ring-shaped electrodes 32 and 33 can effectively shield the electric field from the lines 50, and the problem as above can be suppressed.

However, when a high voltage is applied to the drain region 12, the potential gradient in the region between the gate electrode 31 and the ring-shaped electrode 32 becomes steep, and there is a risk that surface breakdown voltage may deteriorate due to electric field concentration. In particular, when the potential of the drain region 12 and the potential of the ring-shaped electrode 32 are equal and an OFF-voltage is applied to the gate electrode 31, a high potential difference between the gate electrode 31 and the ring-shaped electrode 32 results, which causes a high degree of electric field concentration. As a result, there is a risk that the breakdown voltage of the MOS transistor may deteriorate.

In the present embodiment, at least one of the work function of the electrode portion 31b of the gate electrode 31, which faces the ring-shaped electrode 32, and the work function of the electrode portion 32b of the ring-shaped electrode 32, which faces the gate electrode 31, is different from the work function of the electrode portion 31a of the gate electrode 31. This makes it possible, as described below, to weaken the electric field in the region between the gate electrode 31 and the ring-shaped electrode 32, thereby alleviating electric field concentration and suppressing the aforementioned problem.

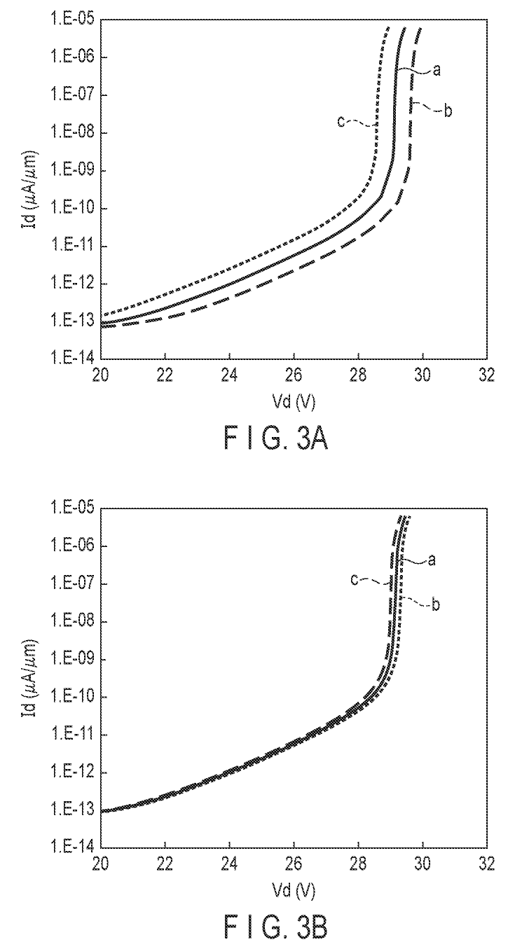

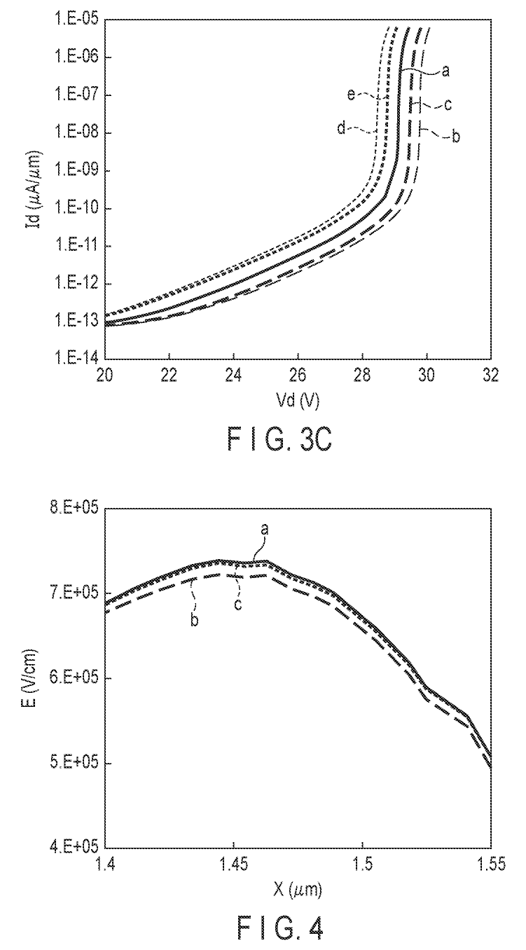

FIG. 3A, FIG. 3B, and FIG. 3C are diagrams showing the relationship between a drain voltage Vd and a drain current Id.

FIG. 3A shows changes in the voltage-current characteristics when the work function of the electrode portion 31b of the gate electrode 31 is changed. In the example shown here, the work function of the electrode portion 32b of the ring-shaped electrode 32 is equal to the work function of the electrode portion 31a of the gate electrode 31. A characteristic curve a represents the case where the work function of the electrode portion 31b of the gate electrode 31 is equal to the work function of the electrode portion 31a of the gate electrode 31. A characteristic curve b represents the case where the work function of the electrode portion 31b is lower than the work function of the electrode portion 31a (the work function difference is 1 eV). A characteristic curve c represents the case where the work function of the electrode portion 31b is higher than the work function of the electrode portion 31a (the work function difference is 1 eV).

As shown in FIG. 3A, relative to the characteristic curve a, the current decreases in the characteristic curve b, and the current increases in the characteristic curve c. As evident from above, when the work function of the electrode portion 31b is made lower than the work function of the electrode portion 31a, an increase in the drain current is suppressed, and degradation of the breakdown voltage due to electric field concentration can be suppressed.

FIG. 3B shows changes in the voltage-current characteristics when the work function of the electrode portion 32b of the ring-shaped electrode 32 is changed. In the example shown here, the work function of the electrode portion 31b of the gate electrode 31 is equal to the work function of the electrode portion 31a of the gate electrode 31. A characteristic curve a represents the case where the work function of the electrode portion 32b of the ring-shaped electrode 32 is equal to the work function of the electrode portion 31a of the gate electrode 31. A characteristic curve b represents the case where the work function of the electrode portion 32b is higher than the work function of the electrode portion 31a (the work function difference is 1 eV). A characteristic curve c represents the case where the work function of the electrode portion 32b is lower than the work function of the electrode portion 31a (the work function difference is 1 eV).

As shown in FIG. 3B, relative to the characteristic curve a, the current decreases in the characteristic curve b, and the current increases in the characteristic curve c. As evident from above, when the work function of the electrode portion 32b is made higher than the work function of the electrode portion 31a, an increase in drain current is suppressed, and degradation of the breakdown voltage due to electric field concentration can be suppressed.

FIG. 3C shows changes in the voltage-current characteristics when the work function of the electrode portion 31b of the gate electrode 31 and the work function of the electrode portion 32b of the ring-shaped electrode 32 are changed.

A characteristic curve a represents the case where the work function of the electrode portion 31b of the gate electrode 31 and the work function of the electrode portion 32b of the ring-shaped electrode 32 are equal to the work function of the electrode portion 31a of the gate electrode 31.

A characteristic curve b represents the case where the work function of the electrode portion 31b is lower than the work function of the electrode portion 31a and the work function of the electrode portion 32b is higher than the work function of the electrode portion 31a. A characteristic curve c represents the case where the work function of the electrode portion 31b is lower than the work function of the electrode portion 31a and the work function of the electrode portion 32b is lower than the work function of the electrode portion 31a. In each case, the work function difference is 1 eV.

A characteristic curve d represents the case where the work function of the electrode portion 31b is higher than the work function of the electrode portion 31a and the work function of the electrode portion 32b is lower than the work function of the electrode portion 31a. A characteristic curve e represents the case where the work function of the electrode portion 31b is higher than the work function of the electrode portion 31a and the work function of the electrode portion 32b is higher than the work function of the electrode portion 31a. In each case, the work function difference is 1 eV.

It can be said that the characteristics shown in FIG. 3A and the characteristics shown in FIG. 3B are reflected in the characteristics shown in FIG. 3C. Accordingly, by appropriately setting the work function of the electrode portion 31b of the gate electrode 31 and the work function of the electrode portion 32b of the ring-shaped electrode 32, the effect described with FIG. 3A and FIG. 3B can be more effectively obtained.

Moreover, relative to the characteristics shown in FIG. 3A and the characteristics shown in FIG. 3B, the influence of changing the work function is larger in the case of FIG. 3A than in the case of FIG. 3B. Therefore, for example, as shown in the characteristic curve c in FIG. 3C, when both the work function of the electrode portion 31b and the work function of the electrode portion 32b are made lower than the work function of the electrode portion 31a, the influence of the electrode portion 31b becomes dominant, and the drain current Id decreases. Accordingly, even in such a case, it is possible to obtain the same effects as described above.

FIG. 4 is a diagram showing an electric field distribution in a region between the gate electrode 31 and the ring-shaped electrode 32. The horizontal axis (abscissa) represents a distance x from the end portion of the gate electrode, and the vertical axis (ordinate) represents an electric field E.

A characteristic curve a represents the case where the work function of the electrode portion 31b of the gate electrode 31 and the work function of the electrode portion 32b of the ring-shaped electrode 32 are equal to the work function of the electrode portion 31a of the gate electrode 31. A characteristic curve b represents the case where the work function of the electrode portion 31b is lower than the work function of the electrode portion 31a (the work function difference is 1 eV). A characteristic curve c represents the case where the work function of the electrode portion 32b is higher than the work function of the electrode portion 31a (the work function difference is 1 eV).

As shown in FIG. 4, relative to the characteristic curve a, the electric field in the region between the gate electrode 31 and the ring-shaped electrode 32 is reduced in the characteristic curve b and the characteristic curve c. In particular, in the characteristic curve b, the electric field is significantly reduced.

As shown in FIG. 3A, FIG. 3B, FIG. 3C, and FIG. 4, by appropriately changing at least one of the work function of the electrode portion 31b of the gate electrode 31 and the work function of the electrode portion 32b of the ring-shaped electrode 32, electric field concentration can be effectively reduced, and degradation of the breakdown voltage can be effectively suppressed.

Next, specific examples of the present embodiment are described.

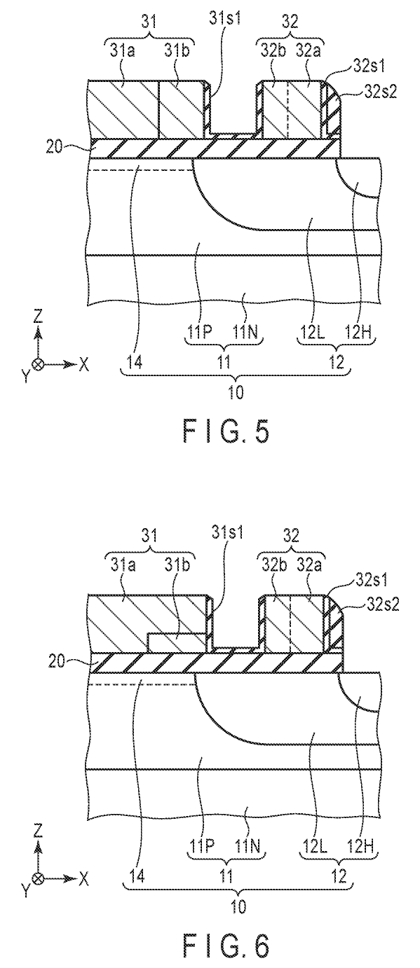

FIG. 5 is a sectional view schematically showing a configuration of a first specific example of the semiconductor device according to the present embodiment.

In the first specific example, the electrode portion 31a of the gate electrode 31 and the electrode portions 32a and 32b of the ring-shaped electrode 32 are formed of the same semiconductor material (for example, N-type polysilicon) having the same work function, and the electrode portion 31b of the gate electrode 31 is formed of a conductive material (for example, a conductive material that is other than semiconductor, such as a metal material) having a lower work function than the work function of the electrode portion 31a. Notably, the sidewall insulating layer 31s includes an inner portion 31s1, and the sidewall insulating layer 32s includes an inner portion 32s1 and an outer portion 32s2.

For example, a structure of the first specific example can be formed by, after forming a pattern of a polysilicon layer, replacing a part of the polysilicon layer by the conductive material such as a metal material.

FIG. 6 is a sectional view schematically showing a configuration of a second specific example of the semiconductor device according to the present embodiment.

Also in the second specific example, the electrode portion 31a of the gate electrode 31 and the electrode portions 32a and 32b of the ring-shaped electrode 32 are formed of the same semiconductor material (for example, N-type polysilicon) having the same work function, and the electrode portion 31b of the gate electrode 31 is formed of a conductive material (for example, a conductive material that is other than semiconductor, such as a metal material) having a lower work function than the work function of the electrode portion 31a. Moreover, in the second specific example, the electrode portion 31a includes a portion that is positioned on the electrode portion 31b.

For example, a structure of the second specific example can be formed by, after forming a first polysilicon layer, replacing a part of the polysilicon layer by the conductive material such as a metal material, and furthermore, forming a second polysilicon layer.

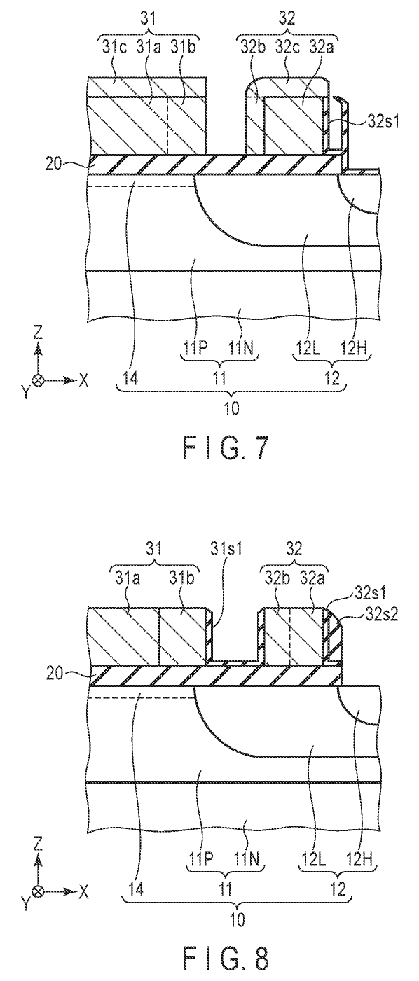

FIG. 7 is a sectional view schematically showing a configuration of a third specific example of the semiconductor device according to the present embodiment.

In the third specific example, the electrode portions 31a and 31b of the gate electrode 31 and the electrode portion 32a of the ring-shaped electrode 32 are formed of the same semiconductor material (for example, N-type polysilicon) having the same work function, and the electrode portion 32b of the ring-shaped electrode 32 is formed of a conductive material (for example, a conductive material that is other than semiconductor, such as a silicide material) having a higher work function than the work function of the electrode portion 31a.

Moreover, in the third specific example, the gate electrode 31 includes an electrode portion 31c that is positioned on the electrode portions 31a and 31b, and the ring-shaped electrode 32 includes an electrode portion 32c that is positioned on the electrode portions 32a and 32b. The electrode portion 32b, the electrode portion 31c, and the electrode portion 32c are formed of the same silicide material.

For example, a structure of the third specific example can be formed by, after forming a pattern of a polysilicon layer and when making an upper portion of the polysilicon layer a silicide, also making a lateral portion of the ring-shaped electrode 32 a silicide in the same process.

FIG. 8 is a sectional view schematically showing a configuration of a fourth specific example of the semiconductor device according to the present embodiment.

In the fourth specific example, the electrode portion 31a of the gate electrode 31 and the electrode portions 32a and 32b of the ring-shaped electrode 32 are formed of the same metal material having the same work function, and the electrode portion 31b of the gate electrode 31 is formed of a different metal material from the metal material of the electrode portions 31a, 32a, and 32b. The work function of the electrode portion 31b is lower than the work function of the electrode portions 31a, 32a, and 32b.

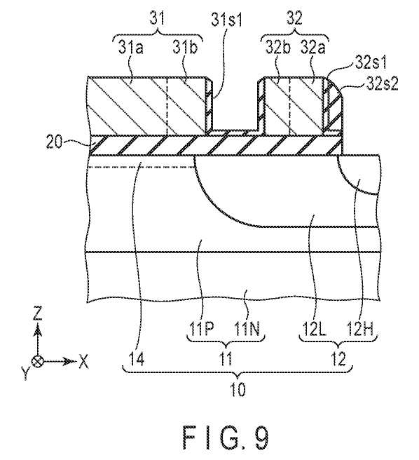

FIG. 9 is a sectional view schematically showing a configuration of a fifth specific example of the semiconductor device according to the present embodiment.

In the fifth specific example, the electrode portions 31a and 31b of the gate electrode 31 are formed of the same metal material having the same work function, and the electrode portions 32a and 32b of the ring-shaped electrode 32 are formed of the same metal material having the same work function. The metal material of the electrode portions 32a and 32b is different from the metal material of the electrode portions 31a and 31b, and the work function of the electrode portions 32a and 32b is higher than the work function of the electrode portions 31a and 31b.

By using the structures as described in the first to fifth specific examples above, the effect as described for the aforementioned embodiment can be obtained.

Notably, in the aforementioned embodiment, the first specific example, and the second specific example, when N-type polysilicon is used as the semiconductor material for the electrode portion 31a of the gate electrode 31, for the material having a lower work function than the work function of the electrode portion 31a of the gate electrode 31, there can be used, for example, a material such as magnesium (Mg), indium (In), manganese (Mn), hafnium (Hf), samarium (Sm), erbium (Er), holmium (Ho), ytterbium (Yb), europium (Eu), praseodymium (Pr), erbium silicide (ErSi₂), or ytterbium silicide (YbSi₂).

Moreover, in the aforementioned embodiment and the third specific example, when N-type polysilicon is used as the semiconductor material for the electrode portion 31a of the gate electrode 31, for the material having a higher work function than the work function of the electrode portion 31a of the gate electrode 31, there can be used, for example, a material such as molybdenum (Mo), nickel (Ni), cobalt (Co), palladium (Pd), copper (Cu), tungsten (W), gold (Au), platinum (Pt), aluminum (Al), chromium (Cr), tin (Sn), tantalum nitride (TaN), nickel silicide (NiSi₂), or platinum silicide (PtSi).

Moreover, in the aforementioned embodiment and the fourth specific example, when tungsten (W), molybdenum (Mo), or copper (Cu) is used as the metal material for the electrode portion 31a of the gate electrode 31, for the material having a lower work function than the work function of the electrode portion 31a of the gate electrode 31, there can be used, for example, a material such as aluminum (Al), tin (Sn), silver (Ag), chromium (Cr), magnesium (Mg), indium (In), or manganese (Mn).

Moreover, in the aforementioned embodiment and the fifth specific example, when tungsten (W), molybdenum (Mo), or copper (Cu) is used as the metal material for the electrode portion 31a of the gate electrode 31, for the material having a higher work function than the work function of the electrode portion 31a of the gate electrode 31, there can be used, for example, a material such as cobalt (Co), nickel (Ni), platinum (Pt), gold (Au), or tantalum nitride (TaN).

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a semiconductor region including a drain region, a source region, and a channel region between the drain region and the source region;
an insulating layer provided on the semiconductor region;
a gate electrode provided on the insulating layer above the channel region;
a drain contact connected to the drain region; and
a first ring-shaped electrode that is provided on the insulating layer to be spaced from the gate electrode and is provided so as to surround the drain contact, wherein
the gate electrode includes a first electrode portion that is in contact with the insulating layer, and a second electrode portion that is adjacent to the first electrode portion, the second electrode portion including a portion that is in contact with the insulating layer and faces the first ring-shaped electrode,
the first ring-shaped electrode includes a third electrode portion that is in contact with the insulating layer, and a fourth electrode portion that is adjacent to the third electrode portion, the fourth electrode portion including a portion that is in contact with the insulating layer and faces the gate electrode, and
a work function of the second electrode portion or the fourth electrode portion is different from a work function of the first electrode portion.

2. The semiconductor device of claim 1, the work function of the second electrode portion or the fourth electrode portion is different from the work function of the first electrode portion by at least 0.2 eV and at most 1.6 eV.

3. The semiconductor device of claim 1, wherein
the work function of the second electrode portion is different from the work function of the first electrode portion, and
the work function of the fourth electrode portion is equal to the work function of the first electrode portion.

4. The semiconductor device of claim 3, wherein
the work function of the second electrode portion is lower than the work function of the first electrode portion.

5. The semiconductor device of claim 1, wherein
the work function of the fourth electrode portion is different from the work function of the first electrode portion, and
the work function of the second electrode portion is equal to the work function of the first electrode portion.

6. The semiconductor device of claim 5, wherein
the work function of the fourth electrode portion is higher than the work function of the first electrode portion.

7. The semiconductor device of claim 1, wherein
the work function of the second electrode portion and the work function of the fourth electrode portion are each different from the work function of the first electrode portion.

8. The semiconductor device of claim 7, wherein
the work function of the second electrode portion is lower than the work function of the first electrode portion, and
the work function of the fourth electrode portion is higher than the work function of the first electrode portion.

9. The semiconductor device of claim 1, wherein
the work function of the third electrode portion is equal to the work function of the first electrode portion.

10. The semiconductor device of claim 1, wherein
the work function of the third electrode portion is equal to the work function of the fourth electrode portion.

11. The semiconductor device of claim 1, further comprising:
a source contact connected to the source region; and
a second ring-shaped electrode that is provided on the insulating layer to be spaced from the gate electrode and is provided so as to surround the source contact.

12. The semiconductor device of claim 1, wherein
a material of the first electrode portion is a semiconductor material.

13. The semiconductor device of claim 12, wherein
a material of the second electrode portion is a conductive material other than semiconductor and has a lower work function than the work function of the first electrode portion.

14. The semiconductor device of claim 12, wherein
a material of the fourth electrode portion is a conductive material other than semiconductor and has a higher work function than the work function of the first electrode portion.

15. The semiconductor device of claim 1, wherein
the first electrode portion includes a portion that is positioned on the second electrode portion.

16. The semiconductor device of claim 1, wherein
the gate electrode further includes a fifth electrode portion that is positioned on the first electrode portion and on the second electrode portion,
the first ring-shaped electrode further includes a sixth electrode portion that is positioned on the third electrode portion and on the fourth electrode portion, and
the fourth electrode portion, the fifth electrode portion, and the sixth electrode portion are formed of the same silicide material.

17. The semiconductor device of claim 1, wherein
a material of the first electrode portion is a metal material.

18. The semiconductor device of claim 17, wherein
a material of the second electrode portion is a metal material that has a lower work function than the work function of the first electrode portion.

19. The semiconductor device of claim 17, wherein
a material of the fourth electrode portion is a metal material that has a higher work function than the work function of the first electrode portion.

20. A semiconductor device comprising:
a semiconductor region including a drain region, a source region, and a channel region between the drain region and the source region in a first direction;
an insulating layer provided on the semiconductor region;
a gate electrode in contact with the insulating layer above the channel region in a second direction perpendicular to the first direction;
a drain contact connected to the drain region; and
a first ring-shaped electrode in contact with the insulating layer, spaced apart from the gate electrode in the first direction, and surrounding the drain contact when viewed in the second direction, wherein
the gate electrode includes a first electrode portion and a second electrode portion that is closer to the first ring-shaped electrode than the first electrode portion,
the first ring-shaped electrode includes a third electrode portion and a fourth electrode portion that is closer to the gate electrode than the third electrode portion, and
a work function of the second electrode portion or the fourth electrode portion is different from a work function of the first electrode portion by at least 0.2 eV and at most 1.6 eV.
